(19) United States
(12) Patent Application Publication
(10) Pub. No.: US 2026/0096039 A1
(43) Pub. Date: Apr. 2, 2026

(54) Secure Storage Container for Above Ground Exterior Storage of Electronic Components

(71) Applicant: Digital Closets, LLC, Buckhead, GA (US)

(72) Inventors: Matthew Schulze, Buckhead, GA (US); Kurt McLaughlin, Buckhead, GA (US)

(73) Assignee: Digital Closets, LLC, Buckhead, GA (US)

(21) Appl. No.: 18/903,218

(22) Filed: Oct. 1, 2024

(51) Int. Cl. H05K 5/02

(52) U.S. Cl. CPC H05K 5/0247; H05K 5/0209; H05K 5/0221

(57) ABSTRACT

A metal storage container for secure above ground exterior storage of electronic subassemblies. One or more slidable partitions are provided in the interior volume of the storage container and are electrically coupled to a panel of the storage container. The storage container is mechanically affixed to an adjacent metal display panel support structure using affixing means to define a ground path therethrough. Electronic components within the storage container are securely protected from environmental factors and ESD using thermal insulation coatings, active low power cooling and redundant ESD protection.

### CROSS REFERENCE TO RELATED APPLICATIONS

N/A

### STATEMENT REGARDING FEDERALLY SPONSORED RESEARCH OR DEVELOPMENT

N/A

### NAMES OF PARTIES TO A JOINT RESEARCH AGREEMENT

N/A

### INCORPORATION BY REFERENCE STATEMENT

N/A

### BACKGROUND OF THE INVENTION

Large electronic display systems, billboards and digital scoreboards have become common place in public locations due in part to reduced manufacturing costs of light emissive devices (LED) arising out of advances in semiconductor manufacturing processes and quantum well structure efficiencies in such devices.

The above electronic display systems, referred to collectively herein as “display systems” generally comprise large two-dimensional arrays of individual display subpanels that are “tiled” on the display system. The subpanels are mounted to an electrical backplane element that connects to the plurality of subpanels to provide electrical power, ground and control signals, all of which are provided to modulate the light output of the LEDs of each subpanel, and consequently to modulate the overall displayed image on the display panel itself as seen by an observer.

Such display panels are now considered as almost a required element at sports and concert venues, large public events, as well as in consumer advertising in the form of advertising billboards placed along major freeways and commercial buildings.

Because these display systems are often situated in outdoor areas and subject to damaging environmental factors such as heat, cold, rain, snow, vibration and rapid temperature swings that can stress electrical connections on delicate printed circuit assemblies (owing to different coefficients of thermal expansion (CTE) of different materials on a subpanel), a failure of one or more of the individual subpanels or support circuitry is to be expected during the life of the display system. Because of the publicly displayed nature of the display panel, a damaged subpanel or display panel component is preferably replaced quickly to minimize the negative public perception that results from a visible defect in a display system.

To reduce the time needed to bring a failed subpanel or related electronic component of a display system back to operation, the display panel industry has begun to store replacement parts such as frequently replaced subpanel elements, printed circuit assemblies, tools, and the like physically on the display panel mounting system or structure (i.e., the metal support structure upon which the display panel is affixed). These spare parts and tools are typically stored above ground on the display panel support structure itself such as on a walkway, using an off-the-shelf storage container that may not be well suited for such use.

Prior art storage containers are not intended for such demanding applications and are prone to theft or vandalism, as well as provide limited protection of delicate electronic components, not only from the above environmental factors, but from damage due to unintended electrostatic discharge (ESD), which discharge events can readily exceed 2,000 volts resulting in damage to the nanometer-width gate and insulator structures in an integrated circuit chip.

What is needed is an inexpensive storage device or container that can be mounted above ground and is not easily removable from a display panel support structure, and that overcomes the above deficiencies in the prior art to provide secure storage of spare or replacement electronic subassemblies and components by providing a securable, sealed, environmentally stable, and ESD-protected solution.

### SUMMARY OF THE INVENTION

The present invention relates to secure storage of electronic parts in an environmentally stable and ESD-protected container.

More particularly, the device of the invention relates to a locking metal storage container that can be easily and securely mechanically affixed to a billboard support or display panel element and that provides maximum protection for electronic components stored therein from degrading environmental factors and ESD using active low power cooling and having improved and redundant ESD protection of the storage container itself.

In a first aspect of the invention, a secure storage container is disclosed for electronic components comprising an upper panel, a lower panel, a front panel, a rear panel and a pair of opposing side panels configured to define an interior volume. At least one partition is slidably disposed within the interior volume. Affixing means is provided for mechanically affixing at least one upper panel, lower panel, front panel, rear panel or side panels of the container to an adjacent structure.

In a second aspect of the invention, a ground connection electrically is coupled to the partition and at least one of the upper panel, lower panel, front panel, rear panel or side panels.

In a third aspect of the invention, the ground connection is an electrically conductive manually removable and connectable snap or clip element.

In a fourth aspect of the invention, the affixing means is electrically coupled to the ground connection.

In a fifth aspect of the invention, at least one surface of at least one partition comprises means to dissipate an electrostatic discharge (ESD) through the ground connection.

In a sixth aspect of the invention, the front panel is rotatably connected to the storage container by hinge means.

In a seventh aspect of the invention, the front panel is configured to be selectively locked or secured in a closed position.

In an eighth aspect of the invention, at least one of the upper panel, lower panel, front panel, rear panel or side panel comprises a thermally insulating or thermally resistant coating or surface.

In a ninth aspect of the invention thermal stabilization means is provided and configured to maintain the interior volume within a user-defined temperature range.

These and various additional aspects, embodiments and advantages of the present invention will become apparent to those of ordinary skill in the art upon review of the Detailed Description and any claims to follow herein.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF DRAWINGS

FIG. 1 is a perspective view of the storage container of the invention showing the front panel in a secured, closed position.

FIG. 2 is a perspective view of the storage container of the invention showing the front panel in an unsecured, open position and illustrates a plurality of slidable partitions disposed in the interior volume of the storage container.

FIG. 3 is a top view of the storage container of the invention with the front panel in a secured, closed position and illustrating an embodiment having a pair of Unistrut channel components affixed by rivet nuts and flange bolts on the rear panel for affixing the storage container to an adjacent display panel support structure.

FIG. 4 is a front view of an alternative embodiment the storage container of the invention showing the front panel in an unsecured, open position and illustrating a plurality of slidable partitions disposed in the interior volume each comprising a respect removable ground connection and comprising thermal stabilization means.

The invention and its various embodiments can now be better understood by turning to the following Detailed Description of the preferred embodiments which are presented as illustrated examples of the invention in any subsequent claims in any application claiming priority to this application. It is expressly understood that the invention as defined by such claims may be broader than the illustrated embodiments described below.

### DETAILED DESCRIPTION OF THE INVENTION

Various embodiments and aspects of the invention are described with reference to details discussed below and the accompanying drawings illustrating certain of the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of certain of the embodiments of the present invention.

Reference in the specification to “one embodiment”, “an embodiment” or “some embodiments” means that a particular feature, structure, or characteristic described in conjunction with the embodiment can be included in at least one embodiment of the invention. The appearances of the phrase “in one embodiment” in various places in the specification do not necessarily all refer to the same embodiment.

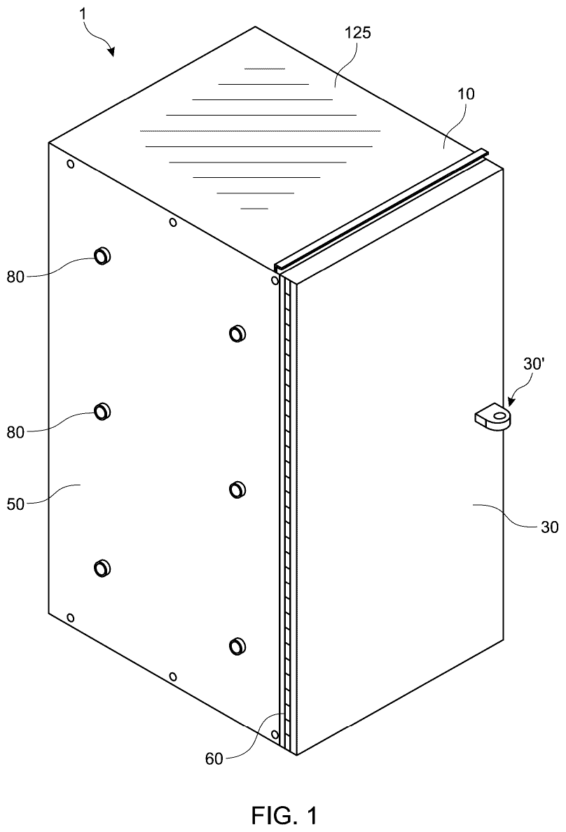

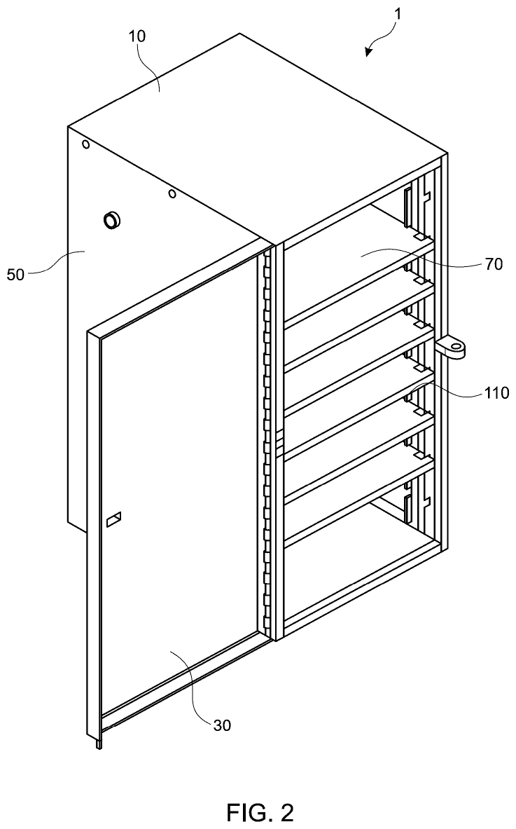

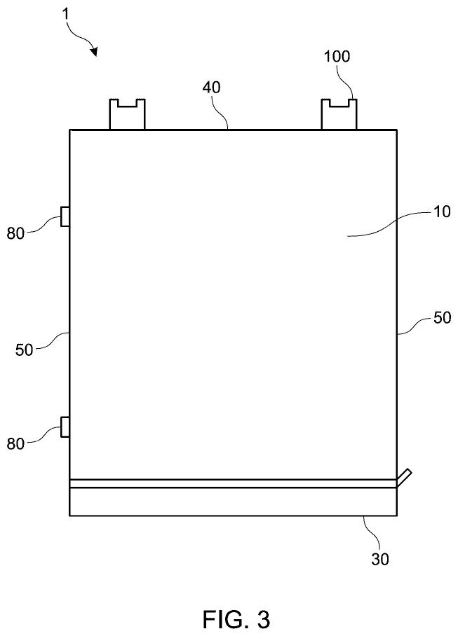

Turning now to the figures, FIG. 1, FIG. 2 and FIG. 3 illustrate a preferred embodiment of storage container 1 of the invention.

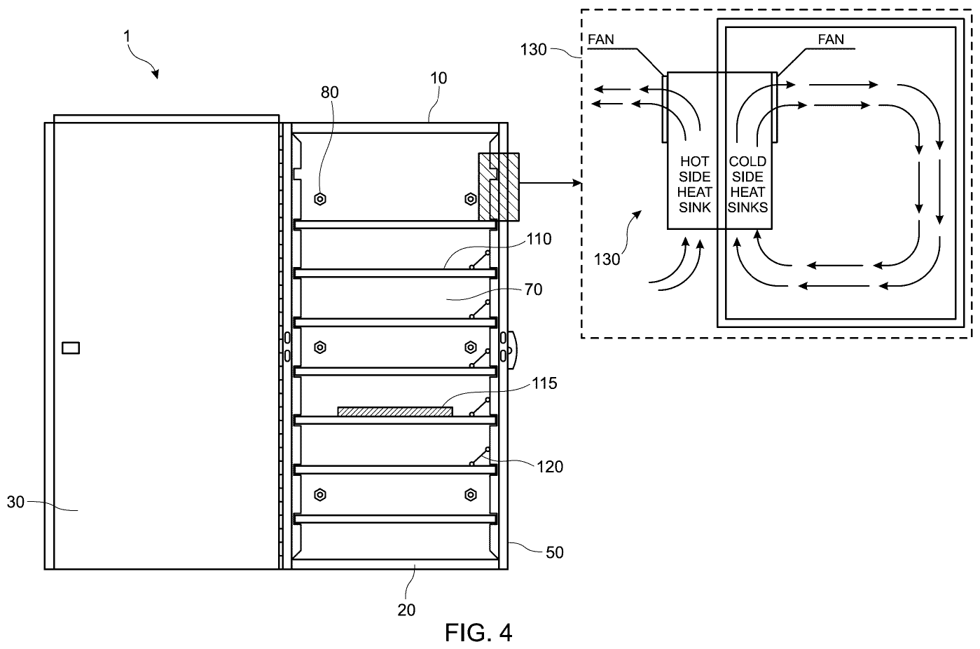

Storage container 1 is preferably fabricated from a suitable gauge sheet metal such as 18-gauge steel sheet metal but may be fabricated from any material having suitable properties such as a plastic or fiberglass material. Storage container 1 comprises an upper panel 10, a lower panel 20 (illustrated in FIG. 4), a front panel 30, a rear panel 40 and a pair of opposing side panels 50. Front panel 30 is rotatably connected to storage container 1 by hinged means 60 such as the illustrated piano hinge connection.

Upper panel 10, lower panel 20, front panel 30, rear panel 40 and respective opposing side panels 50 are connected along their respective peripheries to define interior volume 70.

Front panel 30 is rotatably connected to storage container 1 by hinge means 60 such as the illustrated piano hinge connection to permit the opening and closing of front panel 30. Front panel 30 is preferably configured to be securable in a closed position by means of a hasp and staple element 30′.

It is noted that while the illustrated embodiment is depicted in the vertical or upright orientation whereby front panel 30 rotates about a vertical axis, the installed orientation of the invention is not limited to such an orientation and the invention may be mounted whereby front panel 30 rotates about a horizontal axis or any user-defined axis.

Any of user-selected upper panel 10, lower panel 20, rear panel 40 and/or respective opposing side panels 50 may be provided with affixing means 80 for mechanically affixing storage container 1 to an adjacent metal display panel support structure, such as an upwardly depending metal beam, to define a sturdy, rigid, and electrically conductive connection between them.

In a preferred embodiment, affixing means 80 comprises a plurality of the illustrated preinstalled rivet nuts and respective flange bolts, which flange bolts are preferably only accessible from interior volume 70 for security purposes. The flange bolts and rivet nuts collectively define one or a plurality of threaded structures through the thickness of the selected panel for use in cooperation with, for instance, sturdy, metallic mechanical connection systems such as are available from Unistrut Services Company for mounting on a metal display panel support structure.

In this manner, storage container 1 is electrically coupled to the earth ground provided by the metal display panel support structure itself and enables the electrical grounding of storage container 1. To ensure an adequate ground exists, the electrical resistance between a metal element of storage container 1 and the metal display panel structure should be measured using and ohmmeter to confirm the lowest possible electrical resistance between them.

Rivet nuts may be provided in any user-defined location on the selected panel whereby one or more suitable structural connection means 100 such as one or more of the above Unistrut channel elements can be mounted vertically, horizontally or at one or more user-defined angles.

As best illustrated in FIG. 4, interior volume 70 of storage container 1 may be provided with one or more slidably attached metal shelf elements in the form of one or more interior partitions 110 for the vertical or horizontal storage of, for instance, a planar display panel electronic subassembly.

Partitions 110 may be provided with an ESD protection layer 115 and a selectively removable ground connection 120. This may be in the form of an ESD snap connection or clip that is electrically coupled to a panel of storage container 1 that can be selectively disconnected by a user when partition 110 is being accessed by a user, and reconnected when partition 110 is returned to its closed position and received within interior volume 70.

The upper surface of the one or more of partitions 110 may comprise an ESD protection layer 115 in the form of a vinyl ESD mat element or low-cost planar ESD foam structure for improved ESD protection of the electrical components stored within interior volume 70. In this manner, stored electronic components have greatly reduced risk of ESD damage and a user need only temporarily disconnect ESD strap ground connection 120, remove or slide partition 110 outwardly or upwardly to remove the desired subassembly, then return partition 110 to its closed position and reconnect ESD strap ground connection 120.

It is desirable that at least one end of ESD ground connection 120 be manually removable and connectable without the use of tools such as by means of a snap connection, clip or plug but such an embodiment is not required. For instance, in a non-limiting example using a fixed ESD connection, an extended length of ground connection cable may be provided to permit a user to slide out a partition 110 while maintaining the ground connection. This may be achieved by, for instance, providing a conductive cable element of ground connection 120 of sufficient length that there is cable slack to allow the partition to be withdrawn by a user without breaking the ground path from partition 110 to the panels of storage container 1 to which the ESD ground strap is connected.

The lateral or perimeter portions of front panel 30, the opening of storage container 1 within which front panel 30 is received, or both are preferably provided with an electrically conductive weatherstripping or door seal element to inhibit water penetration to interior volume 70 and minimize potential ESD damage to the electrical subassemblies therein

To minimize thermal conduction from the environment or from direct sun (which can cause exposed metal surfaces to exceed 160 F), to the subpanels stored within storage container 1, the exterior surfaces, interior surfaces or both of upper panel 10, lower panel 20, front panel 30, rear panel 40 and respective opposing side panels 50 may be coated with a thermally insulating layer 125 material or coating as is known in the surface coating industry as depicted in FIG. 1.

In this embodiment, it is important the thermal coating does not interfere with the electrical conductivity between storage container 1 and the metal display panel support structure to which it is affixed to maintain the lowest resistance possible and maximize ESD protection.

Such metal mechanical connections systems are desirable for use with the invention in that a very low electrical resistance connection may be obtained between the metal panels of the storage container 1, the metal rivet nuts and flange bolts when electrically coupled to the metal affixing means 80 components, which in turn are electrically coupled to the metal display panel support structure of the display system itself.

To minimize corrosion and increase conductivity between storage container 1 and the display panel support structure to which the panel is attached, an electrically conductive material such as a conductive grease material may be applied at the connection.

The electrical resistance between storage container 1 and the display panel support structure should be tested at installation using an ohmmeter and at regular intervals to ensure the electrical resistance to ground remains within a user-defined resistance limit.

In an alternate embodiment of FIG. 4, one or more of upper panel 10, lower panel 20, front panel 30, rear panel 40 and respective opposing side panels 50 comprise thermal stability means 130 which may comprise a low power Peltier thermoelectric cooler assembly, or vapor phase chamber, thermal system heat pump assembly, or similar cooling means.

Such thermal stability means 130 should be configured to maintain a stable temperature within internal volume 70, preferably in the range of 50 F to 80 F for electrical subassemblies. The selected temperature set point of temperature stability means 130 should be considered in view of environmental humidity and to address concerns regarding the moisture content and condensation issues that may be detrimental to the electrical subassemblies stored in the invention. To enhance humidity control within interior volume 70, a replaceable desiccant element or material may be included therein.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

Many alterations and modifications may be made by persons having ordinary skill in the art without departing from the spirit and scope of the invention. Therefore, it must be understood that the illustrated embodiments have been set forth only for the purposes of example and that it should not be taken as limiting the invention as defined by any claims in any subsequent application claiming priority to this application.

For example, notwithstanding the fact that the elements or limitations of a claim may be set forth in a certain combination, it must be expressly understood that the invention includes other combinations of fewer, more or different elements or limitations, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus, if an element can be understood in the context of this specification as including more than one meaning, then its use in a subsequent claim must be understood as being generic to all possible meanings supported by the specification and by the word itself.

The definitions of the words or elements of any claims in any subsequent application claiming priority to this application should be, therefore, defined to include not only the combination of elements which are literally set forth, but all equivalent structures, materials or acts for performing substantially the same function in substantially the same way to obtain substantially the same result. In this sense, it is therefore contemplated that an equivalent substitution of two or more elements may be made for any one of the elements in such claims below or that a single element may be substituted for two or more elements in such a claim.

Although elements may be described above as acting in certain combinations and even subsequently claimed as such, it is to be expressly understood that one or more elements from a claimed combination can in some cases be excised from the combination and that such claimed combination may be directed to a sub-combination or variation of a sub-combination.

Insubstantial changes from any subsequently claimed subject matter as viewed by a person with ordinary skill in the art, now known or later devised, are expressly contemplated as being equivalently within the scope of such claims. Therefore, obvious substitutions now or later known to one with ordinary skill in the art are defined to be within the scope of the defined elements.

Any claims in any subsequent application claiming priority to this application are thus to be understood to include what is specifically illustrated and described above, what is conceptually equivalent, what can be obviously substituted and also what essentially incorporates the essential idea of the invention.

What is claimed:

1. A secure storage container for electronic components comprising:
an upper panel, a lower panel, a front panel, a rear panel and a pair of opposing side panels configured to define an interior volume;
at least one partition slidably disposed within the interior volume;
affixing means for mechanically affixing at least one upper panel, lower panel, front panel, rear panel or side panels of the container to an adjacent structure.

2. The container of claim 1 further comprising a ground connection electrically coupled to the partition and at least one of the upper panel, lower panel, front panel, rear panel or side panels.

3. The container of claim 2 wherein the ground connection comprises an electrically conductive manually removable and connectable snap or clip element.

4. The container of claim 2 wherein the affixing means is electrically coupled to the ground connection.

5. The container of claim 2 wherein a surface of at least one partition comprises means to dissipate an electrostatic discharge (ESD) through the ground connection.

6. The container of claim 1 wherein the front panel is rotatably connected to the storage container by hinge means.

7. The container of claim 1 wherein the front panel is configured to be selectively locked or secured in a closed position.

8. The container of claim 1 wherein at least one of the upper panel, lower panel, front panel, rear panel or side panel comprises a thermally insulating or thermally resistant coating or surface.

9. The container of claim 1 further comprising thermal stabilization means configured to maintain the interior volume within a user-defined temperature range.
